(19) United States
(12) Patent Application Publication
(10) Pub. No.: US 2018/0269260 A1
(43) Pub. Date: Sep. 20, 2018

(54) QUANTUM DOT ARRAY ON DIRECTLY PATTERNED AMOLED DISPLAYS AND METHOD OF FABRICATION

(71) Applicant: eMagin Corporation, Hopewell Junction, NY (US)

(72) Inventors: Amalkumar P. GHOSH, Hopewell Junction, NY (US); Evan P. DONOGHUE, Hopewell Junction, NY (US); Ilyas I. KHAYRULLIN, Hopewell Junction, NY (US); Qi WANG, Hopewell Junction, NY (US); Tariq ALI, Hopewell Junction, NY (US)

(21) Appl. No.: 15/986,294

(22) Filed: May 22, 2018

Related U.S. Application Data
(63) Continuation-in-part of application No. 15/882,364, filed on Jan. 29, 2018.
(60) Provisional application No. 62/451,747, filed on Jan. 29, 2017.

(51) Int. Cl. H01L 27/32

(52) U.S. Cl. CPC H01L 27/322; H01L 27/3211; G09G 3/3208; H01L 27/3244; H01L 27/3232

(57) ABSTRACT

An active matrix OLED apparatus comprises a plurality of pixels each including a layer of three sub-pixel anodes, a transparent cathode layer, and a layer of three sub-pixel OLED emitters disposed between the layer of three sub-pixel anodes and the cathode layer. Each of the plurality of pixels further includes a quantum dot semiconductor nanocrystal layer disposed above the transparent cathode layer, the quantum dot layer comprising a first quantum dot sub-pixel layer having a photoluminescent emission in a first red color wavelength range substantially between 780 to 622 nm, wherein the first quantum dot sub-pixel layer being disposed over one of the three sub-pixel OLED emitters having a light emission wavelength in the first red color wavelength range. The OLED apparatus further includes a controller configured to independently address each of the three sub-pixel OLED emitters via the transparent cathode layer and each of the three sub-pixel anodes.

### CROSS-REFERENCE TO RELATED APPLICATIONS

This application claims the benefit of U.S. Provisional Application No. 62/451,747 filed Jan. 29, 2017, which is incorporated herein by reference, and is a Continuation-in-Part of U.S. Non-Provisional application Ser. No. 15/882,364, filed on Jan. 29, 2018 which is also incorporated herein by reference.

### FIELD OF THE INVENTION

The present invention relates to light emitting devices. In particular, the present invention relates to a filter design and filter patterning method for directly patterned organic light emitting diode (“OLED”) devices.

### BACKGROUND

Currently, OLED display technology utilizes two general approaches to deliver color images. The first approach utilizes a color display that produces a white light emission from a common white light OLED stack. The white light emission is filtered through three single color filter layers residing on three adjacent sub-pixels to produce red, green and blue colors (alternatively referred to herein as RGB colors). However, the three RBG color filters residing on the corresponding three adjacent sub-pixels filter all but one wavelength range from the white emissive OLED, and thereby significantly attenuate the emissive intensity of each OLED stack.

The second approach addresses the reduction in intensity of the OLED by providing a color display that includes three entirely different color OLED stacks residing on three adjacent individually driven sub-pixels to produce red, green, and blue (RGB) color emissions due to the distinct configuration of organic layers within the individually designed OLED stacks.

Therefore, a need exists to color correct individually driven red, green, and blue color emitters to tune each required RBG color emitter to expand the color gamut of each sub-pixel of the plurality of sub-pixels that make up the OLED display, particularly since generating deeply saturated colors is currently limited by RGB OLED material development

### SUMMARY

It should be appreciated that the following Summary is provided to introduce a selection of concepts in a simplified form that are further described below in the Detailed Description. This Summary is not intended to be used to limit the scope of the claimed subject matter.

One illustrative embodiment includes an active matrix OLED apparatus comprising a plurality of pixels, each of the plurality of pixels including a layer of three sub-pixel anodes, a transparent cathode layer, and a layer of three sub-pixel OLED emitters disposed between the layer of three sub-pixel anodes and the cathode layer, each of the three sub-pixel OLED emitters corresponding to the three sub-pixel anodes, respectively. The OLED apparatus further comprises a quantum dot semiconductor nanocrystal layer disposed above the transparent cathode layer, the quantum dot layer comprises a first quantum dot sub-pixel layer having a photoluminescent emission in a first wavelength range substantially between 780 to 622 nm, wherein the first quantum dot sub-pixel layer may be disposed over one of the three sub-pixel OLED emitters having a light emission wavelength in the first wavelength range. The OLED apparatus further comprises a controller configured to independently address each of the three sub-pixel OLED emitters via the transparent cathode layer and each of the three sub-pixel anodes.

In another illustrative embodiment, the quantum dot semiconductor nanocrystal layer may be disposed above the transparent cathode layer further comprises a second quantum dot sub-pixel layer having a photoluminescent emission in a second wavelength range substantially between 577 to 492 nm.

In another illustrative embodiment, the second quantum dot sub-pixel layer may be disposed over another one of the three sub-pixel OLED emitters having a light emission wavelength in the second wavelength range. In an alternative illustrative embodiment, the second quantum dot sub-pixel layer may be disposed over another one of the three sub-pixel OLED emitters having a light emission wavelength in a third wavelength range substantially between 492 to 455 nm.

Another illustrative embodiment includes an active matrix OLED apparatus comprising a plurality of pixels, each of the plurality of pixels including a layer of three sub-pixel anodes, a transparent cathode layer, and a layer of three sub-pixel OLED emitters disposed between the layer of three sub-pixel anodes and the cathode layer, each of the three sub-pixel OLED emitters corresponding to the three sub-pixel anodes, respectively. The OLED apparatus further includes a quantum dot semiconductor nanocrystal layer disposed above the transparent cathode layer, the quantum dot layer comprises a first quantum dot sub-pixel layer having a photoluminescent emission in a first wavelength range substantially between 780 to 622 nm, wherein the first quantum dot sub-pixel layer may be disposed over one of the three sub-pixel OLED emitters having a light emission wavelength in a second wavelength range substantially between 577 to 492 nm. The OLED apparatus further includes a controller configured to independently address each of the three sub-pixel OLED emitters via the transparent cathode layer and each of the three sub-pixel anodes.

In another illustrative embodiment, the quantum dot layer further comprises a second quantum dot sub-pixel layer having a photoluminescent emission in the second wavelength range.

In another illustrative embodiment, the second quantum dot sub-pixel layer may be disposed over another one of the three sub-pixel OLED emitters having a light emission wavelength in the second wavelength range. In an alternative illustrative embodiment, the second quantum dot sub-pixel layer may be disposed over another one of the three sub-pixel OLED emitters having a light emission wavelength in a third wavelength range substantially between 492 to 455 nm.

In another illustrative embodiment, an active matrix OLED apparatus comprises a plurality of pixels, each of the plurality of pixels including a layer of three sub-pixel anodes, a transparent cathode layer, and a layer of three sub-pixel OLED emitters disposed between the layer of three sub-pixel anodes and the cathode layer, each of the three sub-pixel OLED emitters corresponding to the three sub-pixel anodes, respectively. The OLED apparatus further includes a quantum dot semiconductor nanocrystal layer disposed above the transparent cathode layer, the quantum dot layer comprises a first quantum dot sub-pixel layer having a photoluminescent emission in a first wavelength range substantially between 780 to 622 nm, wherein the first quantum dot sub-pixel layer may be disposed over one of the three sub-pixel OLED emitters having a light emission wavelength in a second wavelength range substantially between 492 to 455. The OLED apparatus further includes a controller configured to independently address each of the three sub-pixel OLED emitters via the transparent cathode layer and each of the three sub-pixel anodes.

In another illustrative embodiment, the quantum dot layer further comprises a second quantum dot sub-pixel layer having a photoluminescent emission in a third wavelength range substantially between 577 to 492 nm.

In another illustrative embodiment, the second quantum dot sub-pixel layer may be disposed over another one of the three sub-pixel OLED emitters having a light emission wavelength in the second wavelength range. In an alternative illustrative embodiment, the second quantum dot sub-pixel layer may be disposed over another one of the three sub-pixel OLED emitters having a light emission wavelength in the third wavelength range.

### BRIEF DESCRIPTION OF THE SEVERAL VIEWS OF THE DRAWINGS

The illustrative embodiments of the invention will be better understood from the following detailed description with reference to the drawings, which are not necessarily drawing to scale and in which:

FIGS. 1A-1C illustrate a fabrication sequence of a directly patterned OLED display;

FIG. 1A illustrates a first step in fabrication of a the directly patterned OLED display where the anodes are patterned upon a silicon backplane;

FIG. 1B illustrates a second step in fabrication of a the directly patterned OLED display where a hole injection layer, a hole transport layer and red, green and blue emissive layers are patterned upon the partial build-up of FIG. 1A;

FIG. 1C illustrates a third step in fabrication of a the directly patterned OLED display where an electron transport layer, a cathode and a thin film encapsulation are patterned upon the partial build-up of FIG. 1B;

FIGS. 2A-2D illustrates a first illustrative embodiment of the OLED sub-pixel of the directly patterned OLED display;

FIG. 2A illustrates patterning a red, green and blue color filter upon the partial build-up of FIG. 1C;

FIG. 2B illustrates patterning a transparent organic layer on the partial build-up of FIG. 2A;

FIG. 2C illustrates patterning an adhesive layer on the partial build-up of FIG. 2B;

FIG. 2D illustrates adjoining a cover glass layer on the partial build-up of FIG. 2C, thereby illustrating a completed sub-pixel of the first illustrative embodiment;

FIGS. 3A-3D illustrates a second illustrative embodiment of the OLED sub-pixel of the directly patterned OLED display;

FIG. 3A illustrates patterning a red, green and blue color filter upon the partial build-up of FIG. 1C;

FIG. 3B illustrates patterning a transparent organic layer on the partial build-up of FIG. 3A;

FIG. 3C illustrates patterning an adhesive layer on the partial build-up of FIG. 3B;

FIG. 3D illustrates adjoining a cover glass layer on the partial build-up of FIG. 3C, thereby illustrating a completed sub-pixel of the second illustrative embodiment;

FIG. 4 illustrates a color gamut calculation using NTSC 1987 depicting an uncorrected/unfiltered directly patterned OLED display;

FIG. 5 illustrates a color gamut calculation using NTSC 1987 depicting a corrected/filtered directly patterned OLED display;

FIG. 6A illustrates a wavelength vs. normalized intensity chart for the color blue depicting spectra with and without a blue color filter;

FIG. 6B illustrates a wavelength vs. normalized intensity chart for the color green depicting spectra with and without a green color filter;

FIG. 6C illustrates a wavelength vs. normalized intensity chart for the color red depicting spectra with and without a blue red filter;

FIG. 6D illustrates a table showing a standard DP (direct pattern) OLED 1931 CIE-x and 1931 CIE-y values for unfiltered red, green and blue emissions;

FIG. 6E illustrates a table showing an enhanced gamut DP (direct pattern) OLED 1931 CIE-x and 1931 CIE-y values for filtered red, green and blue emissions;

FIG. 7 illustrates a logic flow diagram of a first illustrative embodiment of a method of fabrication an OLED sub-pixel;

FIG. 8 illustrates a logic flow diagram of a second illustrative embodiment of a method of fabrication an OLED sub-pixel;

FIG. 9 illustrates a computer system according to an exemplary illustrative embodiment configured to drive an OLED array using the directly patterned OLED display of the first and second illustrative embodiments depicted in FIGS. 1-3D;

FIG. 10A illustrates a first illustrative embodiment of a quantum dot layer applied over a sub-pixel of an active-matrix organic light emitting diode;

FIG. 10B illustrates a second illustrative embodiment of a quantum dot layer applied over a sub-pixel of an active-matrix organic light emitting diode;

FIG. 10C illustrates a third illustrative embodiment of a quantum dot layer applied over a sub-pixel of an active-matrix organic light emitting diode;

FIG. 11A illustrates a fourth illustrative embodiment of a quantum dot layer applied over a sub-pixel of an active-matrix organic light emitting diode;

FIG. 11B illustrates a fifth illustrative embodiment of a quantum dot layer applied over a sub-pixel of an active-matrix organic light emitting diode;

FIG. 11C illustrates a sixth illustrative embodiment of a quantum dot layer applied over a sub-pixel of an active-matrix organic light emitting diode;

FIG. 12A illustrates a seventh illustrative embodiment of a quantum dot layer applied over a sub-pixel of an active-matrix organic light emitting diode;

FIG. 12B illustrates an eighth illustrative embodiment of a quantum dot layer applied over a sub-pixel of an active-matrix organic light emitting diode; and

FIG. 12C illustrates a ninth illustrative embodiment of a quantum dot layer applied over a sub-pixel of an active-matrix organic light emitting diode.

### DETAILED DESCRIPTION

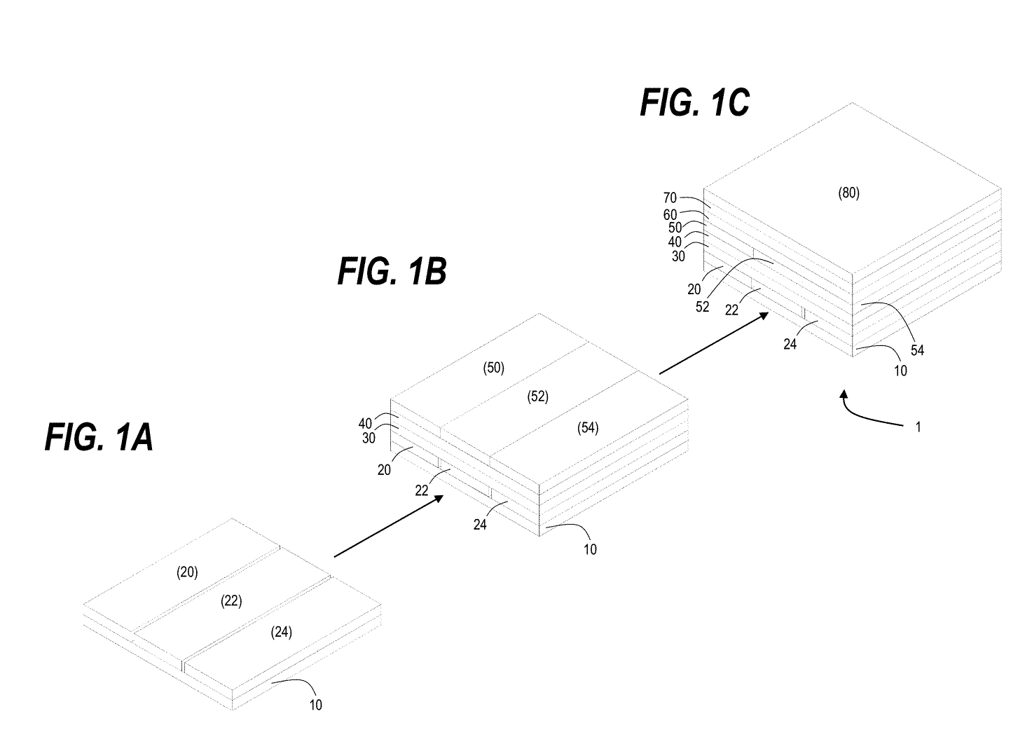

FIGS. 1A-1C illustrate a fabrication sequence of a directly patterned OLED display. An OLED device typically may include a stack of thin layers, or films, formed on a substrate backplane. A variety of technologies may be used to fabricate OLED display backplanes including but not limited to single crystal silicon and polysilicon wafers, glass backplanes with layers of transparent conducting films, and flexible organic or inorganic backplanes.

The thin layers or films of the OLED device may be formed by evaporation, spin casting, other appropriate polymer film-forming techniques, or chemical self-assembly. Thicknesses typically may range from one monolayer to a few thousand angstroms.

In the OLED stack, a light-emitting layer of a luminescent organic solid, as well as adjacent semiconductor layers, is sandwiched between a cathode and an anode. In a typical OLED, either the cathode or the anode is transparent. The light-emitting layer may be selected from any of a multitude of fluorescent organic solids. Any of the layers, and particularly the light-emitting layer, may consist of multiple sub-layers or a single uniform layer.

Protection of OLED stack against oxygen and moisture may be achieved by encapsulation of the device. The encapsulation may be obtained by means of a single thin-film layer situated on the substrate, surrounding the OLED.

FIG. 1A illustrates a first step in fabrication of a directly patterned OLED display of the later described first and second illustrative embodiments where each of the color specific (red, green and blue, or “RGB”) electrode layers 20, 22 and 24 are patterned upon a silicon backplane 10 such that each RGB color specific electrode layer is electrically insulated from adjacent color specific electrode layers. For example, a red electrode layer 20 may correspond to the red OLED stack, a green electrode layer 22 may correspond to the green OLED stack, and a blue electrode layer 24 may correspond to the blue OLED stack. Each of these electrode layers may be substituted for another color or may ordered in a different manner as presented herein. The presentation of this particular order is merely for representative purposes and consistency for the remainder of this disclosure. RGB electrode layers 20, 22 and 24 may be an anode or a cathode, and may be transparent, reflective or opaque.

FIG. 1B illustrates a second step in fabrication of a the directly patterned OLED display where a hole injection layer 30, a hole transport layer 40, and red 50, green 52 and blue 54 emissive layers are patterned upon the partial build-up of FIG. 1A. Red emissive layer 50, green emissive layer 52 and blue emissive layer 54 each comprise discrete color wavelength emitters that have a narrower wavelength than a broad spectrum white light emitter. Each of the color (RGB) emissive layers' color corresponds to the RGB electrode layers 20, 22 and 24 that lies beneath it for the purposes of this disclosure. Each of the RGB emissive layers 50, 52 and 54 may comprise phosphorescent or fluorescent organic solids, and/or quantum dot materials. The RGB emissive layers 50, 52 and 54 may be configured in a tandem OLED structure where plural light-emitting units are stacked in series between the corresponding electrode layers and an electron injection layer.

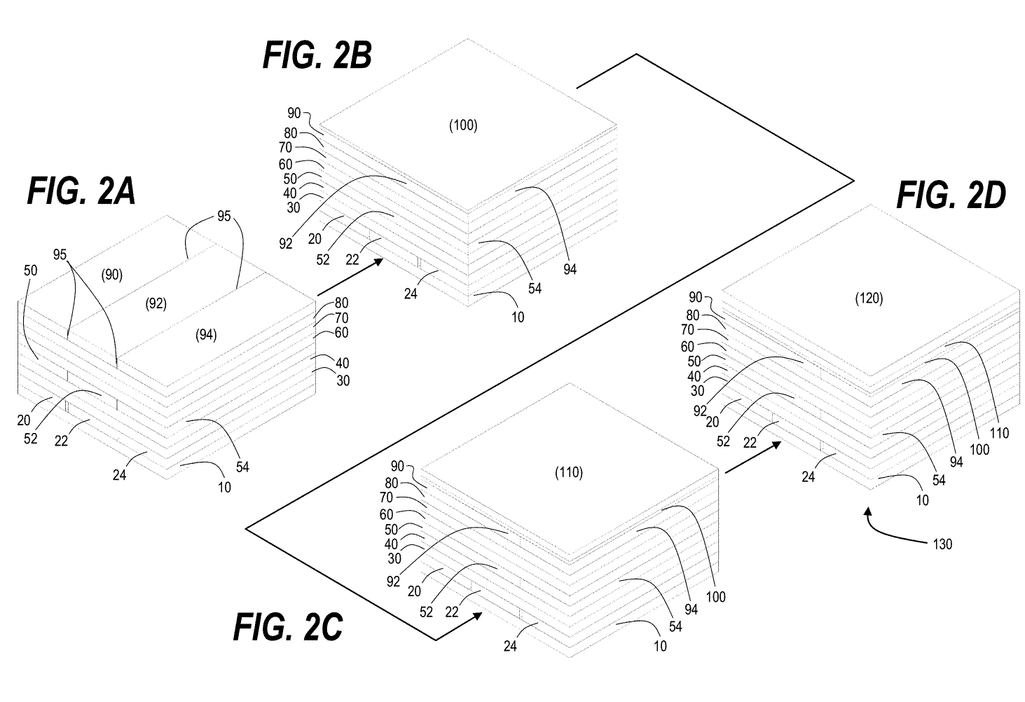

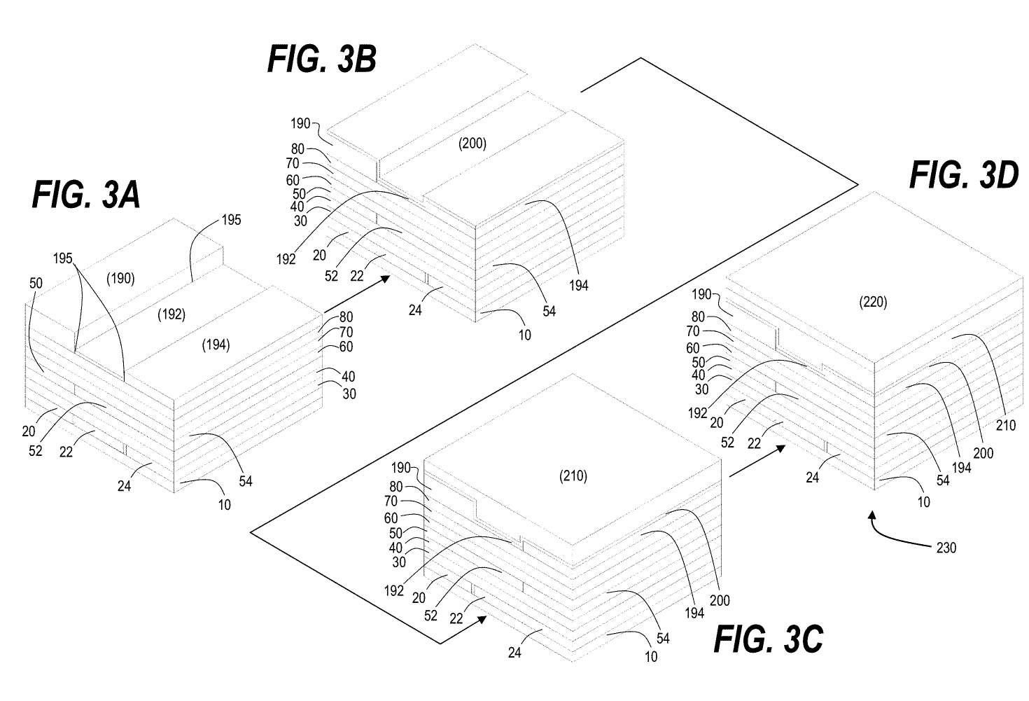

FIG. 1C illustrates a third step in fabrication of a the directly patterned OLED display where an electron transport layer 60, a transparent electrode layer 70 and a thin film encapsulation layer 80 are patterned upon the partial build-up of FIG. 1B. Transparent electrode layer 70 may be an anode or a cathode. Thin film encapsulation layer 80 may be arranged over transparent electrode layer 70 to prevent contamination, by for instance moisture, of RGB emissive layers 50, 52 and 54 or other layers of the sub-pixel. The partial subpixel build-up 1 illustrated in FIG. 1C is the representative starting point for the two illustrative embodiments presented hereinafter, where the first illustrative embodiment is illustrated by FIGS. 2A-2D, and the second illustrative embodiment is illustrated by FIGS. 3A-3D.

FIGS. 2A-2D illustrates a first illustrative embodiment of the OLED sub-pixel of the directly patterned OLED display. FIG. 2A particularly illustrates patterning a corresponding red color filter layer 90, a green color filter layer 92, and a blue color filter layer 94 upon the partial subpixel build-up 1 illustrated in FIG. 1C. Particularly, the red color filter layer 90 is disposed above the transparent electrode layer 70 and the red emissive layer 52; the green color filter layer 92 is disposed above the transparent electrode layer 70 and the green emissive layer 52; and, the blue color filter layer 94 is disposed above the transparent electrode layer 70 and the blue emissive layer 54. The RGB color filter layers 90, 92 and 94 may comprise pigment, dye or inorganic material.

In an alternative illustrative embodiment, the OLED sub-pixel structure may substitute the above-disclosed top emitter type configuration for a bottom emitter type configuration, (not shown), where a color filter(s), (disclosed below), may be patterned prior to the directly patterning a bottom emitter-type RGB color emissive layers 50, 52 and 54.

FIG. 2A in the first illustrative embodiment further graphically illustrates each RGB color filter layer 90, 92 and 94 being substantially the same thickness. Two factors play a major role in the transmissivity of the color filter material used in the RGB color filter layers 90, 92 and 94. First, the chemical and physical compositions of the color filter layers are significant, and second, the thickness of each color filter layer is also significant. The color filter layer thickness is important from a display color saturation standpoint, in that the thicker the color filter layer is, the better the performance of the color filter layer. The RGB color filter layers 90, 92 and 94 may be patterned on top of the respective RBG color emissive layers 50, 52 and 54 array using photolithography, a cover plate with a color filter, or any other equivalent material deposition technique. As discussed below, in some illustrative embodiments, thicknesses may different from color filter to color filter on the same sub-pixel.

Opaque separating layers 95 may extend between adjacent peripheral edges of each color filter layer a top edge of a transparent organic layer 100, (see FIG. 2B). Opaque separating layers 95 may function to prevent visible light from one color sub-pixel from leaking into an adjacent pixel and thereby causing the emission of light outside a desired spectrum. Opaque separating layers 95 may be composed of a filter material including all RGB color filter materials in order to obtain an opaque material. Opaque separating layers 95 may be deposited in the same or similar process step as the deposition of RGB color filter layers 90, 92 and 94.

FIG. 2B illustrates patterning a transparent organic layer 100 on the partial build-up of FIG. 2A and over each of the RGB color filter layers 90, 92 and 94. The transparent organic layer 100 may include multilayer organic and/or inorganic material layers.

FIG. 2C illustrates patterning an adhesive layer 110 on the partial build-up of FIG. 2B directly over the transparent organic layer 100.

FIG. 2D illustrates adjoining a cover layer 120 on the partial build-up of FIG. 2C directly over and adjoined to the adhesive layer, thereby illustrating a completed sub-pixel 130 of the first illustrative embodiment. Cover layer 120 may be glass layer, and/or may be scratch protection layer, non-reflective layer, or a capacitive touch-screen layer. In an alternative illustrative embodiment, an anti-reflective layer (not shown) may be positioned on the back side of cover layer 120 or on the front side of cover layer 120.

FIGS. 3A-3D illustrates a second illustrative embodiment of the OLED sub-pixel of the directly patterned OLED display. FIG. 3A particularly illustrates patterning a corresponding red 190, green 192, and blue 194 color filter layer upon the partial subpixel build-up 1 illustrated in FIG. 1C. Particularly, the red color filter layer 190 is disposed above the transparent electrode layer 70 and the red emissive layer 52; the green color filter layer 192 is disposed above the transparent electrode layer 70 and the green emissive layer 52; and, the blue color filter layer 194 is disposed above the transparent electrode layer 70 and the blue emissive layer 54. The RGB color filter layers 190, 192 and 194 may comprise pigment, dye or inorganic material.

FIG. 3A in the second illustrative embodiment further graphically illustrates each RGB color filter layer 190, 192 and 194 having a substantially different thickness from each other color filter layer. The thickness of each color filter layer is significant in the second illustrative embodiment since the color filter layer thickness is important from a display color tuning standpoint, in that the thickness of each color filter layer may be adjusted to tune or trim a certain range of wavelength emission from the color emission layers. Using the green filter layer 192 as an example, the green filter layer 192 not only blocks red and blue OLED emissive light that may be bleed from adjacent color emissive layers, but the green filter layer 192 may trim a certain portion of the green spectrum emitted by the green emissive layer 52. This trimming via the color filter layers of the individual red, green or blue spectrum emitted by the corresponding color emitter has benefits in both color balancing of the overall OLED display device and increasing the color gamut of each sub-pixel in the OLED display device.

In color balancing, for example, if the green emitter layer 52, without any color filter, has a higher intensity than adjacent red 50 and blue 54 emitter layers without any color filters, then the emitted green light will be stronger than the emitted red and blue light, causing a green shifting in the OLED display when mixing the emitted light of each OLED stack. Color balancing an OLED display requires that the relative transmittance of the three sub-pixels in an RGB OLED display have comparable intensities. In particular, the combination of the light emitted from an RGB display with all three sub-pixels on should be close to a standard white color, for instance point D65 on a 1931 CIE color coordinate graph.

In the second illustrative embodiment, a single-color filter layer may be deposited to a predetermined thickness to compensate for any unbalanced color emitter layer. If the chemical and physical composition of the color filter layers may be adjusted such that a thickness of a color filter layer may corresponds to a particular degree of emitter intensity attenuation, then individual color emitter layer intensities may be adjusted with the application of a deposited color filter layer having a corresponding thickness.

With respect to increasing the color gamut of each sub-pixel in the OLED display device, the chemical and physical compositions of the color filter layers may be adjusted such that a thickness of a color filter layer may correspond to a particular range of wavelength light allowed to pass through the color filter layer from a wider emission spectrum from the color emitter. In this manner, undesirable wavelengths of light emission may be trimmed from the original emitted light to increase the color gamut of each red, green and blue color sub-pixel.

FIGS. 3A-3D illustrate a representative example of different thicknesses of each RGB color filter layer 190, 192 and 194. However, not all color filter layer need be applied to the intermediate pixel stack illustrated in FIG. 1C. If only one color sub-pixel needs adjustment, for example, in intensity or emission spectrum, then only one color filter layer may be applied at the requisite thickness to the corresponding color sub-pixel and the remainder of the color filter layer is left without any deposited color filter layers. Additionally, if two or more color sub-pixels need adjustment, for example, in intensity or emission spectrum, then only two color or more corresponding filter layers may be applied at the requisite thickness to the corresponding color sub-pixels in the same manner.

In an alternative illustrative embodiment, the color filter layers may be comprised of quantum dot material composed of very small semiconductor particles, (typically 2-10 nm in size), that fluoresces light of specific the electromagnetic spectrum frequencies when a current or particular wavelength of light is applied to them. These emitted frequencies can be precisely tuned by changing the quantum dots' size, shape and material. More particularly, when the color emitters excite the quantum dot material, the quantum dots generate a Stokes shift in the quantum dot emitted light capable of achieving more color saturation and a wider color gamut. For example, quantum dotes perform a red-shift of the emitted frequency to a longer wavelength, i.e., a blue wavelength to a green or red wavelength, a green wavelength to a red wavelength, or a red wavelength to a more saturated red wavelength. Quantum dot material may also shift and/or narrow the color spectrum of emitted light.

Opaque separating layers 195 may extend between adjacent peripheral edges of each color filter layer a top edge of a transparent organic layer 200, (see FIG. 3B). Opaque separating layers 195 may function to prevent visible light from one color sub-pixel from leaking into an adjacent pixel and thereby causing the emission of light outside a desired spectrum. Opaque separating layers 195 may be composed of a filter material including all RGB color filter materials to obtain an opaque material. Opaque separating layers 195 may be deposited in the same or similar process step as the deposition of RGB color filter layers 190, 192 and 194.

FIG. 3B illustrates patterning a transparent organic layer 200 on the partial build-up of FIG. 3A and over each of the RGB color filter layers 190, 192 and 194. The transparent organic layer 200 may include multilayer organic and/or inorganic material layers. If one or more color sub-pixels does not need the application of any color filter layer for the reasons identified above, the transparent organic layer 200 would be deposited directly on any non-patterned portion of the thin film encapsulation layer 80

FIG. 3C illustrates patterning an adhesive layer 210 on the partial build-up of FIG. 3B directly over the transparent organic layer 200. The adhesive layer 210 is configured to fill in any unevenness in height resulting in differences in thickness of the RGB color filter layers 190, 192 and 194, or resulting in the lack of application of any color filter layer on the thin film encapsulation layer 80 for the reasons identified above.

FIG. 3D illustrates adjoining a cover layer 220 on the partial build-up of FIG. 3C, thereby illustrating a completed sub-pixel 230 of the second illustrative embodiment. In an alternative illustrative embodiment, an anti-reflective layer (not shown) may be positioned on the back side of cover layer 220 or on the front side of cover layer 220.

The OLED display described herein, in either the first or second illustrative embodiments, may be of both active and passive matrix with any dimension of completed sub-pixels 130 or 230. The display may have any type of a back plane including but not limited to silicon or polysilicon wafer, glass backplane coated with conducting film or films, flexible organic and inorganic backplane or a backplane using combination of both. The active or passive matrix OLED color display may be emitting from either positive current electrode side or negative current electrode side or both sides simultaneously.

The active or passive matrix OLED color display may utilize any type of organic material inside its organic stack including but not limited to small molecule OLED materials, polymer OLED materials, carbon nanotube materials, quantum dot type materials and other materials used to produce light in visible optical band by passing electrical current through the stack. The active or passive OLED color display may utilize any organic or inorganic stack configuration including but not limited to single unit OLED devices, multiunit tandem type OLED devices, stacked OLED devices, with any sequence of the transport and light emitting layers. The active or passive OLED color display may emit light in any color in the visible optical band including but not limited to white, red, green, blue, and yellow.

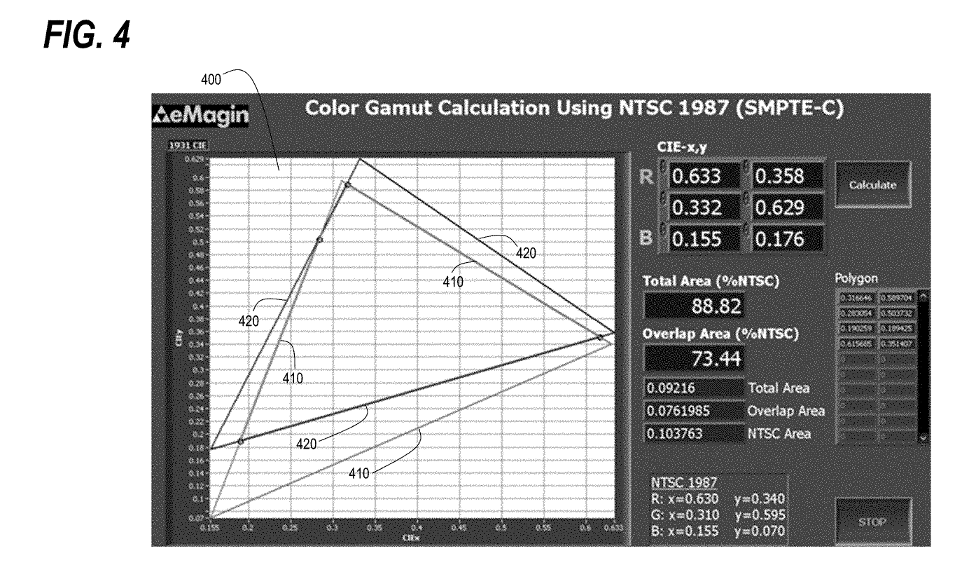

FIG. 4 illustrates an unmodified, (i.e., no color filter layer correction), subpixel color gamut chart 400 using an NTSC 1987 standard gamut color space 410 overlaid with an unmodified sub-pixel gamut color space 420 of a directly patterned OLED display. The unmodified sub-pixel gamut color space 420 encompasses a total area of 88.82% of the NTSC 1987 standard gamut color space 410 and has an overlap area of 73.44% of the NTSC 1987 standard gamut color space 410.

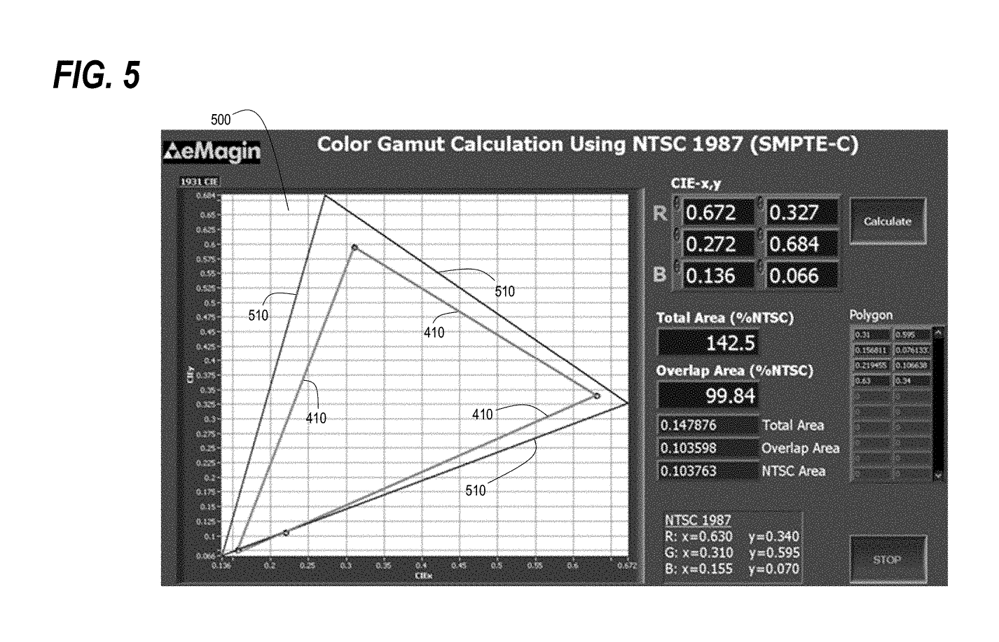

FIG. 5 illustrates a color filter modified color gamut chart 500 using the same NTSC 1987 standard gamut color space 410 but now overlaid with a color filter modified sub-pixel gamut color space 510 of a directly patterned OLED display. The color filter modified sub-pixel gamut color space 510 encompasses a total area of 142.5% of the NTSC 1987 standard gamut color space 410 and has an overlap area of 99.84% of the NTSC 1987 standard gamut color space 410.

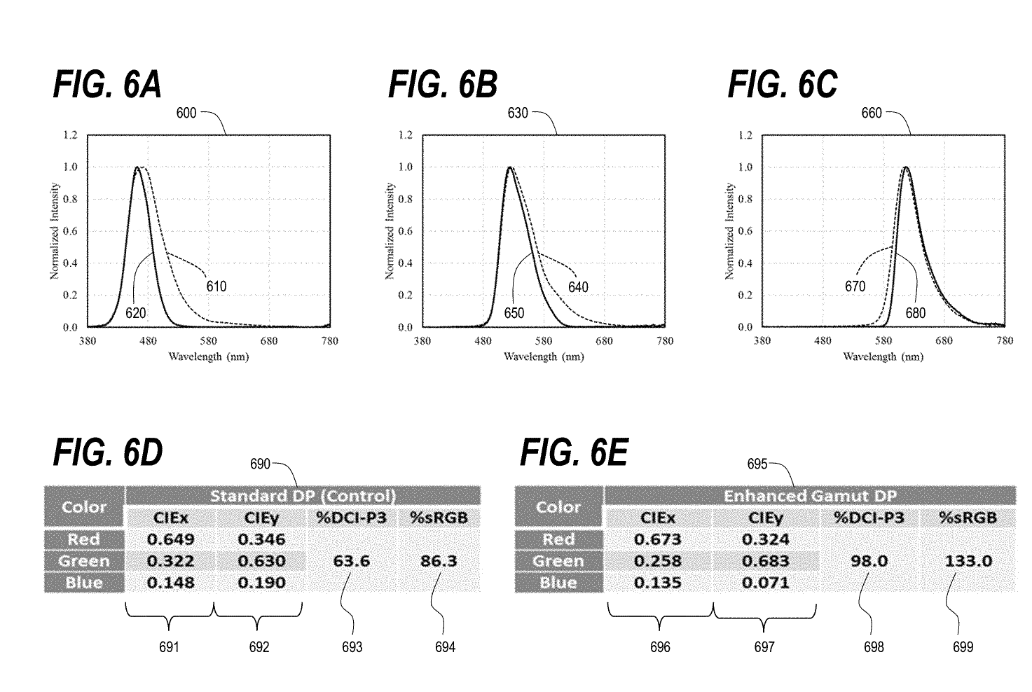

FIG. 6A illustrates a blue wavelength vs. normalized intensity chart 600 depicting an unmodified blue emission spectrum 610 (without any blue color filter layer), and a filtered blue emission spectrum 620 with a blue color filter layer.

FIG. 6B illustrates a green wavelength vs. normalized intensity chart 630 depicting an unmodified green emission spectrum 640 (without any green color filter layer), and a filtered green emission spectrum 650 with a green color filter layer.

FIG. 6C illustrates a red wavelength vs. normalized intensity chart 660 depicting an unmodified red emission spectrum 670 (without any red color filter layer), and a filtered red emission spectrum 680 with a red color filter layer.

FIG. 6D illustrates a standard direction pattern OLED color gamut table 690 displaying color space 1931 CIE-x and 1931 CIE-y coordinates values for unfiltered red, green and blue emission spectrums of a representative sub-pixel RGB. Table 690 shows 1931 CIE-x values 691 for red-x, green-x, and blue-x coordinates, and 1931 CIE-y values 692 for red-y, green-y, and blue-y coordinates. The same unfiltered red, green and blue emission spectrums generate a DCI-P3 color space value 693 of 63.6% based on the following DCI-P3 standard coordinate values:

Rx, Gx, Bx: (0.680, 0.265, 0.150); and

Ry, Gy, By: (0.320; 0.690; 0.060).

The same unfiltered red, green and blue emission spectrums generate a sRGB color space value 694 of 86.3% based on the following sRGB standard coordinate values:

Rx, Gx, Bx: (0.640, 0.300, 0.150); and

Ry, Gy, By: (0.330, 0.600, 0.060).

FIG. 6E illustrates an enhanced, (i.e., color filtered) direct pattern OLED color gamut table 695 showing color space 1931 CIE-x and 1931 CIE-y coordinates values for filtered red, green and blue emission spectrums of a color filter modified sub-pixel. Table 695 shows 1931 CIE-x values 696 for red-x, green-x, and blue-x coordinates, and 1931 CIE-y values 697 for red-y, green-y, and blue-y coordinates. The same filtered red, green and blue emission spectrums generate a DCI-P3 color space value 698 of 98.0% (demonstrating a 54.8% improvement over the unfiltered DCI-P3 value 693 of FIG. 6D), based on the above-identified DCI-P3 coordinate values. The same filtered red, green and blue emission spectrums generate a sRGB color space value 699 of 133.0% (demonstrating a 54.1% improvement over the unfiltered sRGB value of FIG. 6D) based on the above-identified sRGB coordinate values.

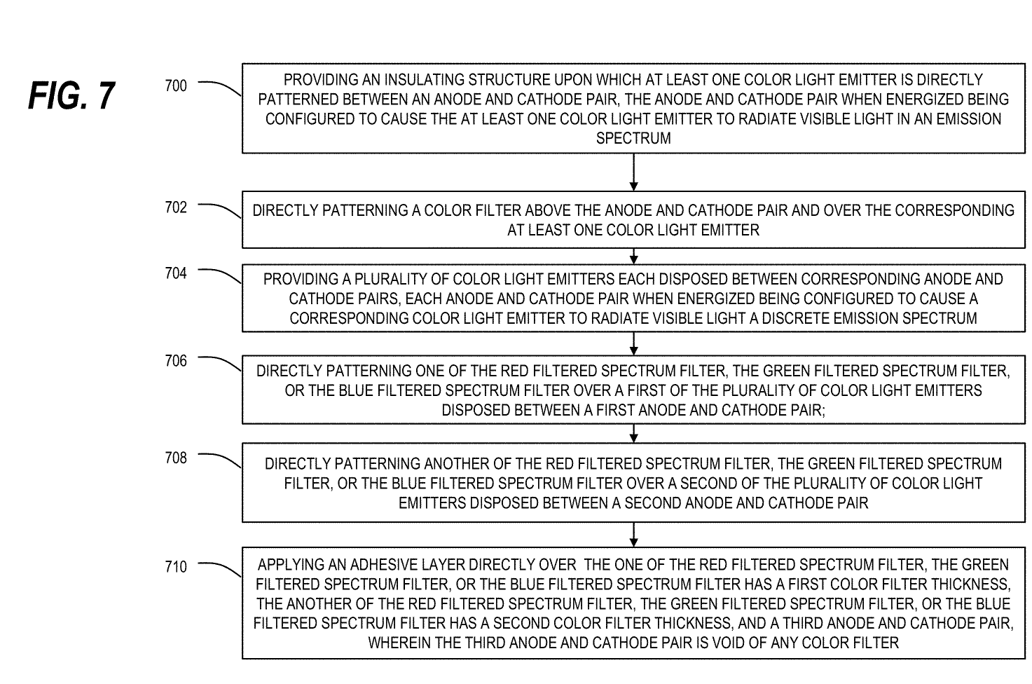

FIG. 7 illustrates a logic flow diagram of a first illustrative embodiment of a method of fabricating an OLED sub-pixel. The method includes providing 700 an insulating structure upon which at least one color light emitter is directly patterned between an anode and cathode pair, the anode and cathode pair when energized being configured to cause the at least one color light emitter to radiate visible light in an emission spectrum, and patterning 702 a color filter above the anode and cathode pair and over the corresponding at least one color light emitter. The method further includes providing 704 a plurality of color light emitters each disposed between corresponding anode and cathode pairs, each anode and cathode pair when energized being configured to cause a corresponding color light emitter to radiate visible light a discrete emission spectrum.

The method further includes patterning 706 one of the red filtered spectrum filter, the green filtered spectrum filter, or the blue filtered spectrum filter over a first of the plurality of color light emitters disposed between a first anode and cathode pair, and patterning 708 another of the red filtered spectrum filter, the green filtered spectrum filter, or the blue filtered spectrum filter over a second of the plurality of color light emitters disposed between a second anode and cathode pair.

The method further includes applying 710 an adhesive layer directly over the one of the red filtered spectrum filter, the green filtered spectrum filter, or the blue filtered spectrum filter has a first color filter thickness, the another of the red filtered spectrum filter, the green filtered spectrum filter, or the blue filtered spectrum filter has a second color filter thickness, and a third anode and cathode pair, wherein the third anode and cathode pair is void of any color filter.

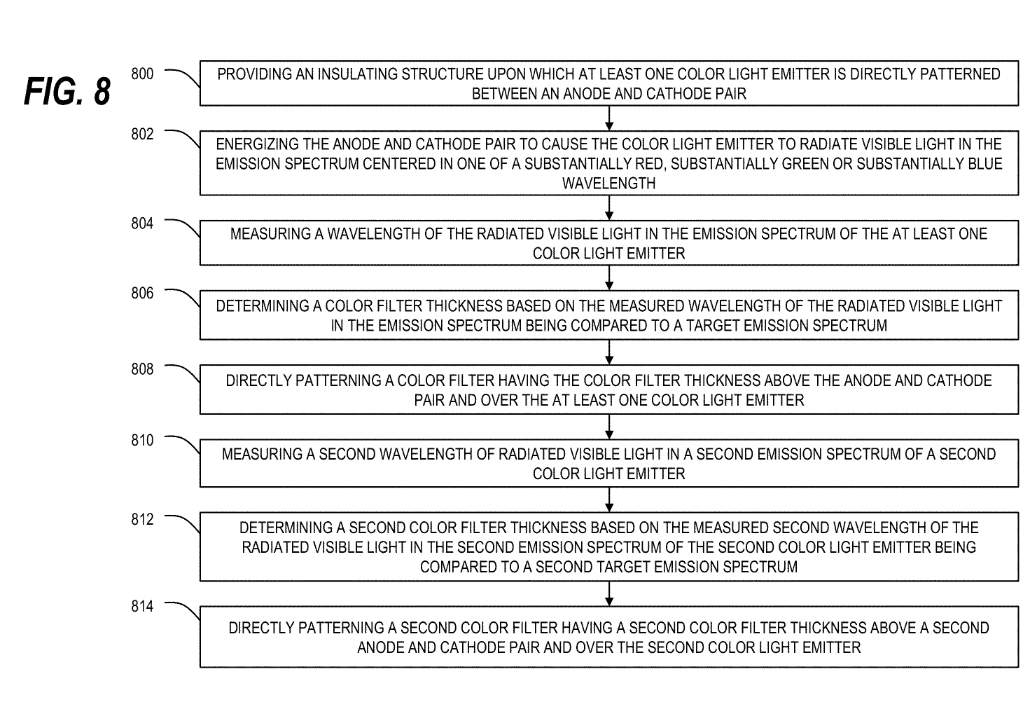

FIG. 8 illustrates a logic flow diagram of a second illustrative embodiment of a method of fabricating an OLED sub-pixel. The method includes providing 800 an insulating structure upon which at least one color light emitter is directly patterned between an anode and cathode pair, and energizing 810 the anode and cathode pair to cause the color light emitter to radiate visible light in the emission spectrum centered in one of a substantially red, substantially green or substantially blue wavelength.

The method further includes measuring 804 a wavelength of the radiated visible light in the emission spectrum of the at least one color light emitter, and determining 806 a color filter thickness based on the measured wavelength of the radiated visible light in the emission spectrum being compared to a target emission spectrum. The method further includes patterning 808 a color filter having the color filter thickness above the anode and cathode pair and over the at least one color light emitter, and measuring 810 a second wavelength of radiated visible light in a second emission spectrum of a second color light emitter.

The method further includes determining 812 a second color filter thickness based on the measured second wavelength of the radiated visible light in the second emission spectrum of the second color light emitter being compared to a second target emission spectrum, and patterning 814 a second color filter having a second color filter thickness above a second anode and cathode pair and over the second color light emitter.

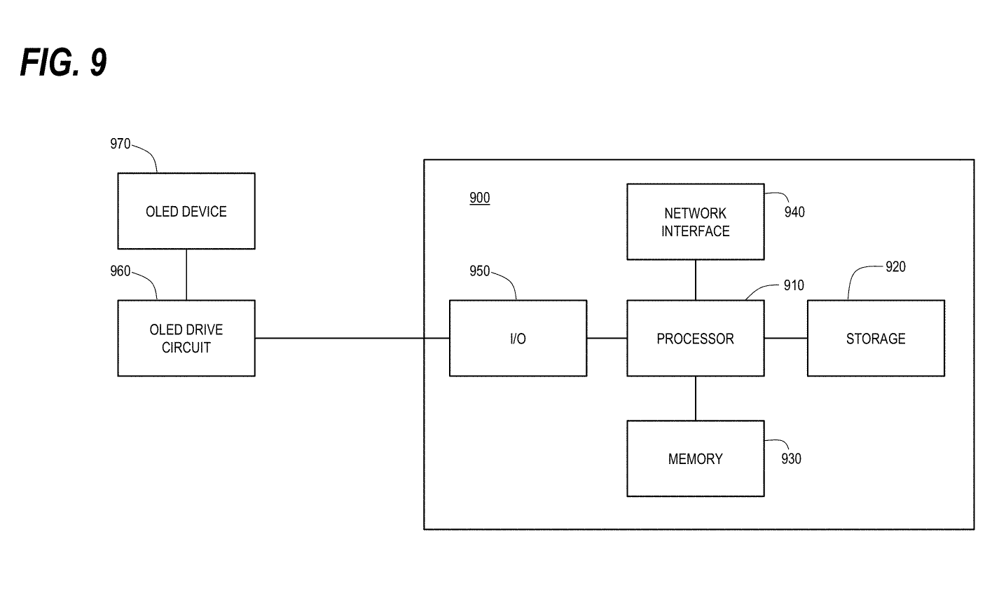

FIG. 9 illustrates a computer system according to an exemplary illustrative embodiment configured to drive an OLED array using the directly patterned OLED display comprised of the completed color filtered sub-pixels 130 and 230 depicted in FIG. 2D and FIG. 3D. Computer 900 can, for example, operate OLED driver circuit 960 that controls and OLED device 970 comprised of a plurality of the completed OLED sub-pixels of the first illustrative embodiment 130 or the completed OLED sub-pixels of the second illustrative embodiment 230.

High resolution active matrix displays may include millions of pixels and sub-pixels that are individually addressed by the OLED drive circuit 960. Each sub-pixel can have several semiconductor transistors and other IC components. Each OLED may correspond to a pixel or a sub-pixel, and these terms are used interchangeably herein.

Additionally, computer 900 can perform the steps described above (e.g., with respect to FIG. 4). Computer 900 contains processor 910 which controls the operation of computer 900 by executing computer program instructions which define such operation, and which may be stored on a computer-readable recording medium. The computer program instructions may be stored in storage 920 (e.g., a magnetic disk, a database) and loaded into memory 930 when execution of the computer program instructions is desired. Thus, the computer operation will be defined by computer program instructions stored in memory 930 and/or storage 920 and computer 900 will be controlled by processor 910 executing the computer program instructions. Computer 900 also includes one or more network interfaces 940 for communicating with other devices, for example other computers, servers, or websites. Network interface 940 may, for example, be a local network, a wireless network, an intranet, or the Internet. Computer 900 also includes input/output 950, which represents devices which allow for user interaction with the computer 900 (e.g., display, keyboard, mouse, speakers, buttons, webcams, etc.). One skilled in the art will recognize that an implementation of an actual computer will contain other components as well, and that FIG. 9 is a high-level representation of some of the components of such a computer for illustrative purposes.

In summary, the inclusion of a color filter layer matching a corresponding color emitter layer has several benefits, namely, the resultant emission spectrum may be more saturated, and the color gamut significantly increased to meet improve device gamut specifications; any undesired portion of the emissive spectrum may be filtered out. Since the color filter layer matches the color of the OLED layer, the emissive light lost is minimized. For example, only non-green light will be filtered from the green pixel, so the bulk of the light is transmitted by the color filter layer lessens any color intensity attenuation by the color filter layer. Further, the thickness of the color filter can be optimized to tune the emissive spectrum color performance which allows a great degree of control over color gamut performance of the OLED device. Additionally, not all color subpixels need to receive a color filter layer, that is, for example, if the performance for two colors is adequate but only one color needs improvement, then only one color in the color filter layer may be applied.

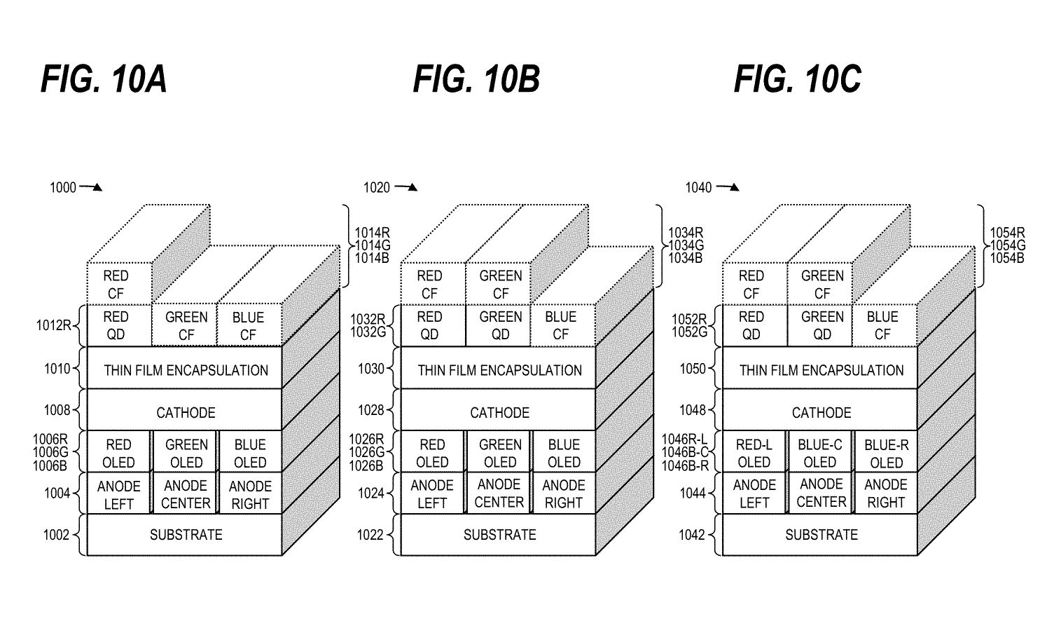

FIGS. 10A-12C illustrate various illustrative embodiments of a pixel using quantum dot (QD) semiconductor nanocrystals that produce pure monochromatic red and green light either used in place of the above-described color filters, or used in conjunction with the color filter upon the directly patterned AMOLED display.

Generally, a quantum dot display is a display device that uses QD semiconductor nanocrystals that produce pure monochromatic red and green light. Photo-emissive or photoluminescent QD particles are used in a QD layer which converts backlight to emit pure basic colors to improve display brightness and color gamut by reducing light losses and color crosstalk of RGB color filters. Quantum dots naturally produce monochromatic light, so they are more efficient than white light sources that must be color filtered and allow more saturated colors that reach nearly 100% of Rec. 2020 color gamut.

QD optoelectronic properties change as a function of both size, shape and material. Larger QDs (radius of 5-6 nm, for example) emit longer wavelengths resulting in emission colors such as orange or red. Smaller QDs (radius of 2-3 nm, for example) emit shorter wavelengths resulting in colors like blue and green, although the specific colors and sizes vary depending on the exact composition of the QD.

Performance of QDs is determined by the size and/or composition of the QD structures. Unlike simple atomic structures, a quantum dot structure has the unusual property that energy levels are strongly dependent on the structure's size. For example, CdSe quantum dot light emission can be tuned from red (5 nm dot diameter) to the violet region (1.5 nm dot diameter). The physical reason for QD coloration is the quantum confinement effect and is directly related to their energy levels. The bandgap energy that determines the energy (and hence color) of the fluorescent light is inversely proportional to the square of the size of quantum dot. Larger QDs have more energy levels that are more closely spaced, allowing the QD to emit (or absorb) photons of lower energy (redder color). In other words, the emitted photon energy increases as the dot size decreases, because greater energy is required to confine the semiconductor excitation to a smaller volume.

A QD array over the directly patterned OLED emitters enable quantum dots to generate a Stokes-type shift in emitted wavelength to emit more saturated colors at a sub-pixel level and therefore a wider color gamut across the OLED array display.

QD particles configured in a layer over OLED emitters may convert or shift emitted light from the OLED emitters to longer wavelengths, i.e., an emitted blue may shift to green or red wavelength, an emitted green wavelength may shift to red wavelength, and an emitted red wavelength shifts to a more saturated red wavelength. However, QDs can only be used to shift to longer wavelengths so they are not helpful for creating a more saturated blue but can be useful for more saturated red or more saturated green.

FIGS. 10A to 10C illustrate a first illustrative embodiment of a quantum dot layer applied over a sub-pixel of an active-matrix organic light emitting diode (AMOLED). In particular, FIGS. 10A to 10C illustrate a sub-pixel component comprising a red wavelength emitting OLED stacked in a vertical configuration with a red photoluminescent QD layer.

FIG. 10A illustrates a pixel 1000 patterned upon a substrate layer 1002 having an anode layer 1004 with three discretely addressable anodes, (illustrated here as left, center and right anodes). Patterned above each respective anode is an emitting OLED layer 1006 including an emitting red OLED 1006R, an emitting green OLED 1006G and an emitting blue OLED 1006B. Above each of the emitting OLED layers 1006 is a transparent cathode layer 1008 configured to provide a conductive path to each of the anodes of the anode layer 1004 to thereby provide an addressable location for each respective colored emitter OLEDs of the emitter OLED layer 1006.

A transparent thin film encapsulation layer 1010 covers the cathode layer 1008 and supports a QD layer 1012 which contains, wherein with respect to this illustrative embodiment, only a red QD sub-pixel layer 1012R patterned above the emitting red OLED 1006R. In this illustrative embodiment, the emissive red OLED 1006R emits a red wavelength of light into the red QD sub-pixel layer 1012R that is shifted to a longer red wavelength depending on the QD particle size, shape and composition of the red QD sub-pixel layer 1012R. This wavelength shifting of the similar colored emitting OLED may cause the finally emitted red light to be more saturated in the red color spectrum than the light emitted from the red OLED emitter 1006R.

An optional color filter layer 1014 may include a red color filter 1014R disposed above the red QD sub-pixel layer 1012R to further narrow the photoluminescent red spectrum luminescing from the red QD sub-pixel layer 1012R. As described above, with respect to FIGS. 1-8, a green color filter 1014G may be disposed above the emissive green OLED 1006G and a blue color filter 1014B may be similarly disposed above the emissive blue OLED 1006B above the thin film encapsulation layer 1010 to narrow the color spectrum of the emitting green and blue light wavelength, respectively.

FIG. 10B illustrates a pixel 1020 patterned upon a substrate layer 1022 having an anode layer 1024 with three discretely addressable anodes, (illustrated here as left, center and right anodes). Patterned above each respective anode is an emitting OLED layer 1026 including an emitting red OLED 1026R, an emitting green OLED 1026G and an emitting blue OLED 1026B. Above each of the emitting OLED layers 1026 is a transparent cathode layer 1028 configured to provide a conductive path to each of the anodes of the anode layer 1024 to thereby provide an addressable location for each respective colored emitter OLEDs of the emitter OLED layer 1026.

A transparent thin film encapsulation layer 1030 covers the cathode layer 1028 and supports a QD layer 1032 which contains, with respect to this illustrative embodiment, a red QD sub-pixel layer 1032R patterned above the emitting red OLED 1026R and a green QD sub-pixel layer 1032G patterned above the emitting green OLED 1026G. In this illustrative embodiment, the emissive red OLED 1026R emits a red wavelength of light into the red QD sub-pixel layer 1032R as described above with respect to FIG. 10A. Additionally, in this illustrative embodiment, the emissive green OLED 1026G emits a green wavelength of light into the green QD sub-pixel layer 1032G that is shifted to a longer green wavelength depending on the QD particle size, shape and composition of the green QD sub-pixel layer 1032G. This wavelength shifting of the similar colored emitting OLED may cause the finally emitted green light to be more saturated in the green color spectrum than the light emitted from the green OLED emitter 1026G.

An optional color filter layer 1034 may include a red color filter 1034R disposed above the red QD sub-pixel layer 1032R to further narrow the photoluminescent red spectrum luminescing from the red QD sub-pixel layer 1032R, and a green color filter 1034G disposed above the green QD sub-pixel layer 1032G to further narrow the photoluminescent green spectrum luminescing from the green QD sub-pixel layer 1032G. As described above, with respect to FIGS. 1-8, a blue color filter 1034B may be similarly disposed above the emissive blue OLED 1026B above the thin film encapsulation layer 1030 to narrow the color spectrum of the emitting blue light wavelength.

FIG. 10C illustrates a pixel 1040 patterned upon a substrate layer 1042 having an anode layer 1044 with three discretely addressable anodes, (illustrated here as left, center and right anodes). (Note that in the following illustrations, the particular position of an emitter OLED device will be referenced with respect to the left “L”, center “C” or right “R” anode under which it is disposed. E.g., where appropriate, the reference number will be followed by a single character designating its color, i.e., red “R”, green “G” or blue “B”, followed by a hyphen to designate its particular position, i.e., “L”, “C” or “R”.)

Patterned above each respective anode is an emitting OLED layer 1046 including an emitting red left OLED 1046R-L, an emitting blue center OLED 1046B-C and an emitting blue right OLED 1046B-R. Above each of the emitting OLED layers 1046 is a transparent cathode layer 1048 configured to provide a conductive path to each of the anodes of the anode layer 1044 to thereby provide an addressable location for each respective colored emitter OLEDs of the emitter OLED layer 1046.

A transparent thin film encapsulation layer 1050 covers the cathode layer 1048 and supports a QD layer 1052 which contains, with respect to this illustrative embodiment, a red QD sub-pixel layer 1052R patterned above the emitting red left OLED 1046R-L and a green QD sub-pixel layer 1052G patterned above the emitting blue center OLED 1046B-C. In this illustrative embodiment, the emissive red left OLED 1046R-L emits a red wavelength of light into the red QD sub-pixel layer 1052R as described above with respect to FIG. 10A. Additionally, in this illustrative embodiment, the emissive blue center OLED 1046B-C emits a blue wavelength of light into the green QD sub-pixel layer 1052G that is shifted to a green wavelength depending on the QD particle size, shape and composition of the green QD sub-pixel layer 1052G.

An optional color filter layer 1054 may include a red color filter 1054R disposed above the red QD sub-pixel layer 1052R to further narrow the photoluminescent red spectrum luminescing from the red QD sub-pixel layer 1052R, and a green color filter 1054G disposed above the green QD sub-pixel layer 1052G to further narrow the photoluminescent green spectrum luminescing from the green QD sub-pixel layer 1052G. As described above, with respect to FIGS. 1-8, a blue color filter 1054B may be similarly disposed above the emissive blue OLED 1046B above the thin film encapsulation layer 1050 to narrow the color spectrum of the emitting blue light wavelength.

In summary, an active matrix OLED apparatus comprises a plurality of pixels as illustrated in FIGS. 10A to 10C, where each of the plurality of pixels includes a layer of three sub-pixel anodes, a transparent cathode layer, and a layer of three sub-pixel OLED emitters disposed between the layer of three sub-pixel anodes and the cathode layer, each of the three sub-pixel OLED emitters corresponding to the three sub-pixel anodes, respectively. Each of the plurality of pixels further includes a quantum dot semiconductor nanocrystal layer disposed above the transparent cathode layer, the quantum dot layer comprises a first quantum dot sub-pixel layer having a photoluminescent emission in a first red color wavelength range substantially between 780 to 622 nm, wherein the first quantum dot sub-pixel layer may be disposed over one of the three sub-pixel OLED emitters having a light emission wavelength in the first wavelength range. The OLED apparatus further includes a controller configured to independently address each of the three sub-pixel OLED emitters via the transparent cathode layer and each of the three sub-pixel anodes.

The OLED apparatus further may comprise a color filter disposed over the first quantum dot sub-pixel layer configured to narrow the wavelength of the photoluminescent emission of the first quantum dot sub-pixel layer.

The quantum dot layer further comprises a second quantum dot sub-pixel layer having a photoluminescent emission in a second green color wavelength range substantially between 577 to 492 nm. In one embodiment, the second quantum dot sub-pixel layer may be disposed over another one of the three sub-pixel OLED emitters having a light emission wavelength in the second wavelength range. A color filter may be disposed over the second quantum dot sub-pixel layer configured to narrow the wavelength of the photoluminescent emission of the second quantum dot sub-pixel layer.

In another alternative embodiment, the second quantum dot sub-pixel layer may be disposed over another one of the three sub-pixel OLED emitters having a light emission wavelength in a third blue color wavelength range substantially between 492 to 455 nm. A color filter may be disposed over the second quantum dot sub-pixel layer configured to narrow the wavelength of the photoluminescent emission of the second quantum dot sub-pixel layer.

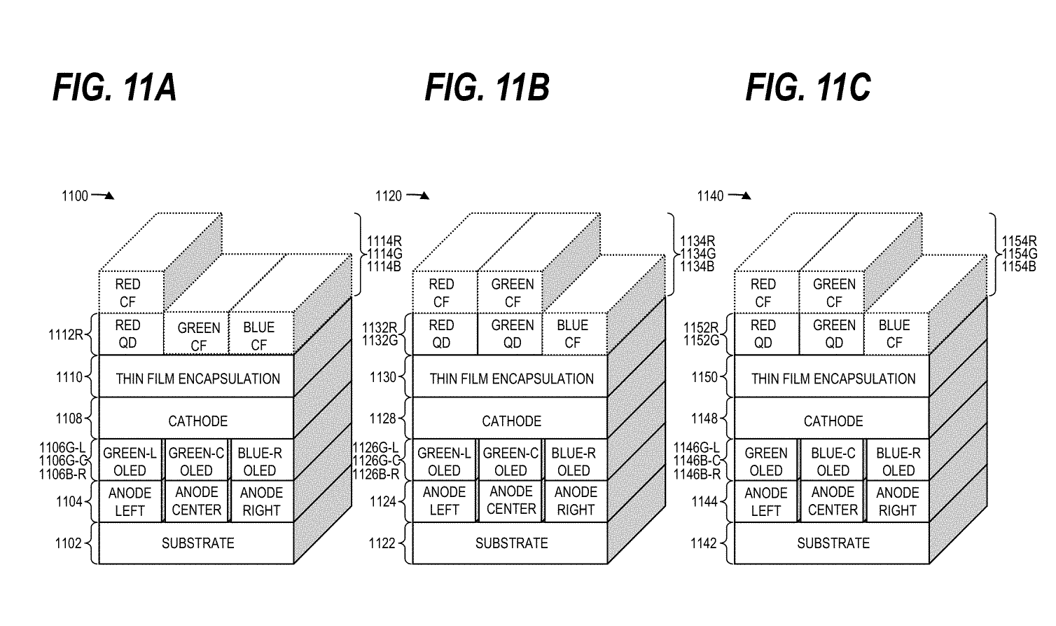

FIGS. 11A to 11C illustrate a second illustrative embodiment of a quantum dot layer applied over a sub-pixel of an active-matrix organic light emitting diode (AMOLED). In particular, FIGS. 11A to 11C illustrate a sub-pixel component comprising a green wavelength emitting OLED stacked in a vertical configuration with a red photoluminescent QD layer.

FIG. 11A illustrates a pixel 1100 patterned upon a substrate layer 1102 having an anode layer 1104 with three discretely addressable anodes, (illustrated here as left, center and right anodes). Patterned above each respective anode is an emitting OLED layer 1106 including an emitting green left OLED 1106G-L, an emitting green center OLED 1106G-C and an emitting blue right OLED 1106B-R. Above each of the emitting OLED layers 1106 is a transparent cathode layer 1108 configured to provide a conductive path to each of the anodes of the anode layer 1104 to thereby provide an addressable location for each respective colored emitter OLEDs of the emitter OLED layer 1106.

A transparent thin film encapsulation layer 1110 covers the cathode layer 1108 and supports a QD layer 1112 which contains, wherein with respect to this illustrative embodiment, only a red QD sub-pixel layer 1112R patterned above the emitting green left OLED 1106G-L. In this illustrative embodiment, the emissive green left OLED 1106G-L emits a green wavelength of light into the red QD sub-pixel layer 1112R that is shifted to a red wavelength depending on the QD particle size, shape and composition of the red QD sub-pixel layer 1112R. This wavelength shifting causes the finally emitted red light from the red QD sub-pixel layer 1112R.

An optional color filter layer 1114 may include a red color filter 1114R disposed above the red QD sub-pixel layer 1112R to further narrow the photoluminescent red spectrum luminescing from the red QD sub-pixel layer 1112R. As described above, with respect to FIGS. 1-8, a green color filter 1114G may be disposed above the emissive green center OLED 1116G-C and a blue color filter 1114B may be similarly disposed above the emissive blue center OLED 1106B-C above the thin film encapsulation layer 1110 to narrow the color spectrum of the emitting green and blue light wavelengths, respectively.

FIG. 11B illustrates a pixel 1120 patterned upon a substrate layer 1122 having an anode layer 1124 with three discretely addressable anodes, (illustrated here as left, center and right anodes). Patterned above each respective anode is an emitting OLED layer 1126 including an emitting green left OLED 1126G-L, an emitting green center OLED 1126G-C and an emitting blue right OLED 1126B-R. Above each of the emitting OLED layers 1126 is a transparent cathode layer 1128 configured to provide a conductive path to each of the anodes of the anode layer 1124 to thereby provide an addressable location for each respective colored emitter OLEDs of the emitter OLED layer 1126.

A transparent thin film encapsulation layer 1130 covers the cathode layer 1128 and supports a QD layer 1132 which contains, with respect to this illustrative embodiment, a red QD sub-pixel layer 1132R patterned above the emitting green lift OLED 1126G-L and a green QD sub-pixel layer 1132G patterned above the emitting green center OLED 1126G-C. In this illustrative embodiment, the emissive green left OLED 1126G-L emits a green wavelength of light into the red QD sub-pixel layer 1132R. Additionally, in this illustrative embodiment, the emissive green center OLED 1126G-C emits a green wavelength of light into the green QD sub-pixel layer 1132G as described above with respect to FIG. 10B. This wavelength shifting of the similar colored emitting OLEDs may cause the finally emitted green light to be more saturated in the green color spectrum than the light emitted from the green OLED emitter 1126G-C.

An optional color filter layer 1134 may include a red color filter 1134R disposed above the red QD sub-pixel layer 1132R to further narrow the photoluminescent red spectrum luminescing from the red QD sub-pixel layer 1132R, and a green color filter 1134G disposed above the green QD sub-pixel layer 1132G to further narrow the photoluminescent green spectrum luminescing from the green QD sub-pixel layer 1132G, as described above with respect to FIG. 10B. As described above, with respect to FIGS. 1-8, a blue color filter 1134B may be similarly disposed above the emissive blue OLED 1126B above the thin film encapsulation layer 1130 to narrow the color spectrum of the emitting blue light wavelength.

FIG. 11C illustrates a pixel 1140 patterned upon a substrate layer 1142 having an anode layer 1144 with three discretely addressable anodes, (illustrated here as left, center and right anodes). Patterned above each respective anode is an emitting OLED layer 1146 including an emitting green left OLED 1146G-L, an emitting blue center OLED 1146B-C and an emitting blue right OLED 1146B-R. Above each of the emitting OLED layers 1146 is a transparent cathode layer 1148 configured to provide a conductive path to each of the anodes of the anode layer 1144 to thereby provide an addressable location for each respective colored emitter OLEDs of the emitter OLED layer 1146.

A transparent thin film encapsulation layer 1150 covers the cathode layer 1148 and supports a QD layer 1152 which contains, with respect to this illustrative embodiment, a red QD sub-pixel layer 1152R patterned above the emitting green left OLED 1146G-L and a green QD sub-pixel layer 1152G patterned above the emitting blue center OLED 1146B-C. In this illustrative embodiment, the emissive green left OLED 1146G-L emits a green wavelength of light into the red QD sub-pixel layer 1152R as described above with respect to FIG. 11A. Additionally, in this illustrative embodiment, the emissive blue center OLED 1146B-C emits a blue wavelength of light into the green QD sub-pixel layer 1152G as described above with respect to FIG. 10C.

An optional color filter layer 1154 may include a red color filter 1154R disposed above the red QD sub-pixel layer 1152R to further narrow the photoluminescent red spectrum luminescing from the red QD sub-pixel layer 1152R, and a green color filter 1154G disposed above the green QD sub-pixel layer 1152G to further narrow the photoluminescent green spectrum luminescing from the green QD sub-pixel layer 1152G. As described above, with respect to FIGS. 1-8, a blue color filter 1154B may be similarly disposed above the emissive blue OLED 1146B above the thin film encapsulation layer 1150 to narrow the color spectrum of the emitting blue light wavelength.

In summary, an active matrix OLED apparatus comprises a plurality of pixels as illustrated in FIGS. 11A to 11C, each of the plurality of pixels including a layer of three sub-pixel anodes, a transparent cathode layer, and a layer of three sub-pixel OLED emitters disposed between the layer of three sub-pixel anodes and the cathode layer, each of the three sub-pixel OLED emitters corresponding to the three sub-pixel anodes, respectively. Each of the plurality of pixels further includes a quantum dot semiconductor nanocrystal layer disposed above the transparent cathode layer, the quantum dot layer comprises a first quantum dot sub-pixel layer having a photoluminescent emission in a first red color wavelength range substantially between 780 to 622 nm, wherein the first quantum dot sub-pixel layer may be disposed over one of the three sub-pixel OLED emitters having a light emission wavelength in a second green color wavelength range substantially between 577 to 492 nm. The OLED apparatus further includes a controller configured to independently address each of the three sub-pixel OLED emitters via the transparent cathode layer and each of the three sub-pixel anodes.

The OLED apparatus further may comprise a color filter disposed over the first quantum dot sub-pixel layer configured to narrow the wavelength of the photoluminescent emission of the first quantum dot sub-pixel layer.

The quantum dot layer further comprises a second quantum dot sub-pixel layer having a photoluminescent emission in the second wavelength range. In one embodiment, the second quantum dot sub-pixel layer may be disposed over another one of the three sub-pixel OLED emitters having a light emission wavelength in the second wavelength range. A color filter disposed over the second quantum dot sub-pixel layer configured to narrow the wavelength of the photoluminescent emission of the second quantum dot sub-pixel layer.

In another alternative embodiment, the second quantum dot sub-pixel layer may be disposed over another one of the three sub-pixel OLED emitters having a light emission wavelength in a third blue color wavelength range substantially between 492 to 455 nm. A color filter may disposed over the second quantum dot sub-pixel layer configured to narrow the wavelength of the photoluminescent emission of the second quantum dot sub-pixel layer.

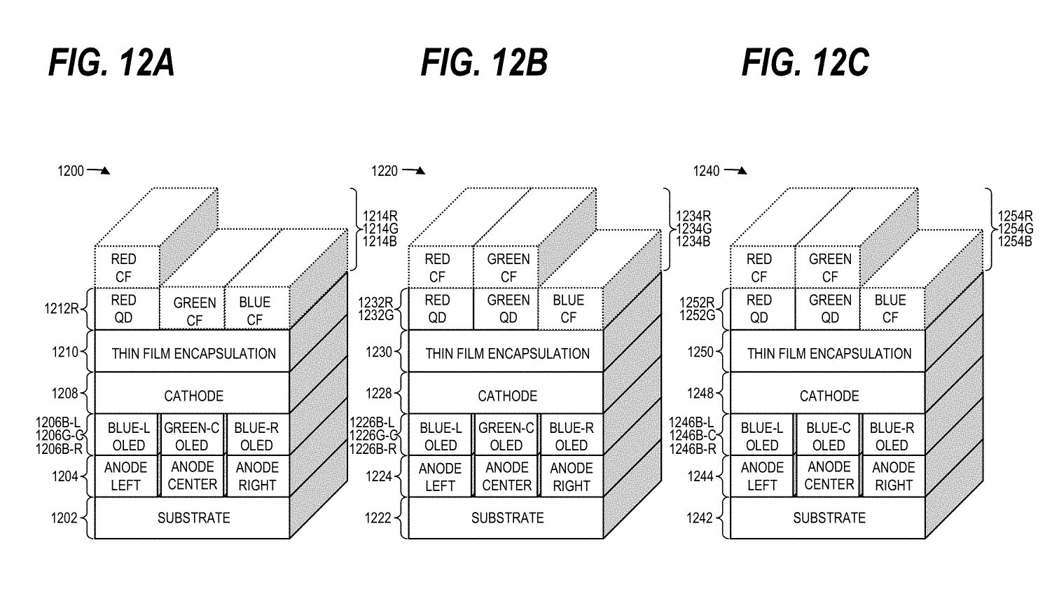

FIGS. 12A to 12C illustrate a third illustrative embodiment of a quantum dot layer applied over a sub-pixel of an active-matrix organic light emitting diode (AMOLED). In particular, FIGS. 12A to 12C illustrate a sub-pixel component comprising a blue wavelength emitting OLED stacked in a vertical configuration with a red photoluminescent QD layer.

FIG. 12A illustrates a pixel 1200 patterned upon a substrate layer 1202 having an anode layer 1204 with three discretely addressable anodes, (illustrated here as left, center and right anodes). Patterned above each respective anode is an emitting OLED layer 1206 including an emitting blue left OLED 1206B-L, an emitting green center OLED 1206G-C and an emitting blue right OLED 1206B-R. Above each of the emitting OLED layers 1206 is a transparent cathode layer 1208 configured to provide a conductive path to each of the anodes of the anode layer 1204 to thereby provide an addressable location for each respective colored emitter OLEDs of the emitter OLED layer 1206.

A transparent thin film encapsulation layer 1210 covers the cathode layer 1208 and supports a QD layer 1212 which contains, wherein with respect to this illustrative embodiment, only a red QD sub-pixel layer 1212R patterned above the emitting blue left OLED 1206B-L. In this illustrative embodiment, the emissive blue left OLED 1206B-L emits a blue wavelength of light into the red QD sub-pixel layer 1212R that is shifted to a red wavelength depending on the QD particle size, shape and composition of the red QD sub-pixel layer 1212R. This wavelength shifting causes the finally emitted red light from the red QD sub-pixel layer 1212R.

An optional color filter layer 1214 may include a red color filter 1214R disposed above the red QD sub-pixel layer 1212R to further narrow the photoluminescent red spectrum luminescing from the red QD sub-pixel layer 1212R. As described above, with respect to FIGS. 1-8, a green color filter 1214G may be disposed above the emissive green center OLED 1206G-C and a blue color filter 1214B may be similarly disposed above the emissive blue right OLED 1206B-R above the thin film encapsulation layer 1120 to narrow the color spectrum of the emitting green and blue light wavelengths, respectively.

FIG. 12B illustrates a pixel 1220 patterned upon a substrate layer 1222 having an anode layer 1224 with three discretely addressable anodes, (illustrated here as left, center and right anodes). Patterned above each respective anode is an emitting OLED layer 1226 including an emitting blue left OLED 1226B-L, an emitting green center OLED 1226G-C and an emitting blue right OLED 1226B-R. Above each of the emitting OLED layers 1226 is a transparent cathode layer 1228 configured to provide a conductive path to each of the anodes of the anode layer 1224 to thereby provide an addressable location for each respective colored emitter OLEDs of the emitter OLED layer 1226.

A transparent thin film encapsulation layer 1230 covers the cathode layer 1228 and supports a QD layer 1232 which contains, with respect to this illustrative embodiment, a red QD sub-pixel layer 1232R patterned above the emitting blue left OLED 1226B-L and a green QD sub-pixel layer 1232G patterned above the emitting green center OLED 1226G-C. In this illustrative embodiment, the emissive blue left OLED 1226B-L emits a blue wavelength of light into the red QD sub-pixel layer 1232R as described above with respect to FIG. 12A. Additionally, in this illustrative embodiment, the emissive green center OLED 1226G-C emits a green wavelength of light into the green QD sub-pixel layer 1232G as described above with respect to FIG. 10B.

An optional color filter layer 1234 may include a red color filter 1234R disposed above the red QD sub-pixel layer 1232R to further narrow the photoluminescent red spectrum luminescing from the red QD sub-pixel layer 1232R, and a green color filter 1234G disposed above the green QD sub-pixel layer 1232G to further narrow the photoluminescent green spectrum luminescing from the green QD sub-pixel layer 1232G, as described above with respect to FIG. 10B. As described above, with respect to FIGS. 1-8, a blue color filter 1234B may be similarly disposed above the emissive blue right OLED 1226B-R above the thin film encapsulation layer 1230 to narrow the color spectrum of the emitting blue light wavelength.

FIG. 12C illustrates a pixel 1240 patterned upon a substrate layer 1242 having an anode layer 1244 with three discretely addressable anodes, (illustrated here as left, center and right anodes). Patterned above each respective anode is an emitting OLED layer 1246 including an emitting blue left OLED 1246B-L, an emitting blue center OLED 1246B-C and an emitting blue right OLED 1246B-R. Above each of the emitting OLED layers 1246 is a transparent cathode layer 1248 configured to provide a conductive path to each of the anodes of the anode layer 1244 to thereby provide an addressable location for each respective colored emitter OLEDs of the emitter OLED layer 1246.

A transparent thin film encapsulation layer 1250 covers the cathode layer 1248 and supports a QD layer 1252 which contains, with respect to this illustrative embodiment, a red QD sub-pixel layer 1252R patterned above the emitting blue left OLED 1246B-L and a green QD sub-pixel layer 1252G patterned above the emitting blue center OLED 1246B-C. In this illustrative embodiment, the emissive blue left OLED 1246B-L emits a blue wavelength of light into the red QD sub-pixel layer 1252R that is shifted to a red wavelength depending on the QD particle size, shape and composition of the red QD sub-pixel layer 1252R. This wavelength shifting causes the finally emitted red light from the red QD sub-pixel layer 1252R. Additionally, in this illustrative embodiment, the emissive blue center OLED 1246B-C emits a blue wavelength of light into the green QD sub-pixel layer 1252G that is shifted to a green wavelength depending on the QD particle size, shape and composition of the green QD sub-pixel layer 1252G. This wavelength shifting causes the finally emitted green light from the green QD sub-pixel layer 1252G.

An optional color filter layer 1254 may include a red color filter 1254R disposed above the red QD sub-pixel layer 1252R to further narrow the photoluminescent red spectrum luminescing from the red QD sub-pixel layer 1252R, and a green color filter 1254G disposed above the green QD sub-pixel layer 1252G to further narrow the photoluminescent green spectrum luminescing from the green QD sub-pixel layer 1252G as described above with respect to FIG. 10B. As described above, with respect to FIGS. 1-8, a blue color filter 1254B may be similarly disposed above the emissive blue right OLED 1246B-R above the thin film encapsulation layer 1250 to narrow the color spectrum of the emitting blue light wavelength.

In summary, an active matrix OLED apparatus comprises a plurality of pixels as illustrated in FIGS. 12A to 12C, each of the plurality of pixels including a layer of three sub-pixel anodes, a transparent cathode layer, and a layer of three sub-pixel OLED emitters disposed between the layer of three sub-pixel anodes and the cathode layer, each of the three sub-pixel OLED emitters corresponding to the three sub-pixel anodes, respectively. Each of the plurality of pixels further includes a quantum dot semiconductor nanocrystal layer disposed above the transparent cathode layer, the quantum dot layer comprises a first quantum dot sub-pixel layer having a photoluminescent emission in a first red color wavelength range substantially between 780 to 622 nm, wherein the first quantum dot sub-pixel layer may be disposed over one of the three sub-pixel OLED emitters having a light emission wavelength in a second blue color wavelength range substantially between 492 to 455. The OLED apparatus further includes a controller configured to independently address each of the three sub-pixel OLED emitters via the transparent cathode layer and each of the three sub-pixel anodes.

The OLED apparatus further may comprise a color filter disposed over the first quantum dot sub-pixel layer configured to narrow the wavelength of the photoluminescent emission of the first quantum dot sub-pixel layer.

The quantum dot layer further comprises a second quantum dot sub-pixel layer having a photoluminescent emission in a third green color wavelength range substantially between 577 to 492 nm. In one embodiment, the second quantum dot sub-pixel layer may be disposed over another one of the three sub-pixel OLED emitters having a light emission wavelength in the second blue color wavelength range. A color filter disposed over the second quantum dot sub-pixel layer configured to narrow the wavelength of the photoluminescent emission of the second quantum dot sub-pixel layer.

In another alternative embodiment, the second quantum dot sub-pixel layer may be disposed over another one of the three sub-pixel OLED emitters having a light emission wavelength in the third green color wavelength range. A color filter disposed over the second quantum dot sub-pixel layer configured to narrow the wavelength of the photoluminescent emission of the second quantum dot sub-pixel layer.

In summary, the inclusion of a quantum dot layer corresponding to a color emitter layer has several benefits, namely, the resultant emission spectrum may be more saturated, and the color gamut significantly increased to meet improve device gamut specifications. Additionally, not all emitter OLEDs need to receive a QD layer, that is, for example, if the performance for two colors is adequate but only one color needs improvement, then only one QD layer may be applied. Furthermore, the ability to use blue and green emitter OLEDs or exclusively blue emitter OLEDs would provide a cost and time savings in manufacturing by eliminating the need for either one color emitter or two color emitters.

While only a limited number of preferred illustrative embodiments have been disclosed for purposes of illustration, it is obvious that many modifications and variations could be made thereto. This disclosure intends to cover all of those modifications and variations which fall within the scope of the present invention, as defined by the following claims.

What is claimed is:

1. An active matrix OLED apparatus comprising:
a plurality of pixels, each of the plurality of pixels including
a layer of three sub-pixel anodes,
a transparent cathode layer,
a layer of three sub-pixel OLED emitters disposed between the layer of three sub-pixel anodes and the cathode layer, each of the three sub-pixel OLED emitters corresponding to the three sub-pixel anodes, respectively,
a quantum dot semiconductor nanocrystal layer disposed above the transparent cathode layer, the quantum dot layer comprises a first quantum dot sub-pixel layer having a photoluminescent emission in a first wavelength range substantially between 780 to 622 nm, wherein the first quantum dot sub-pixel layer being disposed over one of the three sub-pixel OLED emitters having a light emission wavelength in the first wavelength range; and
a controller configured to independently address each of the three sub-pixel OLED emitters via the transparent cathode layer and each of the three sub-pixel anodes.

2. The apparatus of claim 1, further comprising a color filter disposed over the first quantum dot sub-pixel layer configured to narrow the wavelength of the photoluminescent emission of the first quantum dot sub-pixel layer.

3. The apparatus of claim 1, wherein the quantum dot semiconductor nanocrystal layer further comprises a second quantum dot sub-pixel layer having a photoluminescent emission in a second wavelength range substantially between 577 to 492 nm.

4. The apparatus of claim 3, wherein the second quantum dot sub-pixel layer being disposed over another one of the three sub-pixel OLED emitters having a light emission wavelength in the second wavelength range.

5. The apparatus of claim 4, further comprising a color filter disposed over the second quantum dot sub-pixel layer configured to narrow the wavelength of the photoluminescent emission of the second quantum dot sub-pixel layer.

6. The apparatus of claim 1, wherein the quantum dot semiconductor nanocrystal layer further comprises a second quantum dot sub-pixel layer being disposed over another one of the three sub-pixel OLED emitters and having a light emission wavelength in a third wavelength range substantially between 492 to 455 nm.

7. The apparatus of claim 6, further comprising a color filter disposed over the second quantum dot sub-pixel layer configured to narrow the wavelength of the photoluminescent emission of the second quantum dot sub-pixel layer.

8. An active matrix OLED apparatus comprising:
a plurality of pixels, each of the plurality of pixels including
a layer of three sub-pixel anodes,
a transparent cathode layer,
a layer of three sub-pixel OLED emitters disposed between the layer of three sub-pixel anodes and the cathode layer, each of the three sub-pixel OLED emitters corresponding to the three sub-pixel anodes, respectively,
a quantum dot semiconductor nanocrystal layer disposed above the transparent cathode layer, the quantum dot layer comprises a first quantum dot sub-pixel layer having a photoluminescent emission in a first wavelength range substantially between 780 to 622 nm, wherein the first quantum dot sub-pixel layer being disposed over one of the three sub-pixel OLED emitters having a light emission wavelength in a second wavelength range substantially between 577 to 492 nm; and
a controller configured to independently address each of the three sub-pixel OLED emitters via the transparent cathode layer and each of the three sub-pixel anodes.

9. The apparatus of claim 8, further comprising a color filter disposed over the first quantum dot sub-pixel layer configured to narrow the wavelength of the photoluminescent emission of the first quantum dot sub-pixel layer.

10. The apparatus of claim 8, wherein the quantum dot semiconductor nanocrystal layer further comprises a second quantum dot sub-pixel layer having a photoluminescent emission in the second wavelength range.

11. The apparatus of claim 10, wherein the second quantum dot sub-pixel layer being disposed over another one of the three sub-pixel OLED emitters having a light emission wavelength in the second wavelength range.

12. The apparatus of claim 11, further comprising a color filter disposed over the second quantum dot sub-pixel layer configured to narrow the wavelength of the photoluminescent emission of the second quantum dot sub-pixel layer.

13. The apparatus of claim 8, wherein the quantum dot semiconductor nanocrystal layer further comprises a second quantum dot sub-pixel layer being disposed over another one of the three sub-pixel OLED emitters and having a light emission wavelength in a third wavelength range substantially between 492 to 455 nm.

14. The apparatus of claim 13, further comprising a color filter disposed over the second quantum dot sub-pixel layer configured to narrow the wavelength of the photoluminescent emission of the second quantum dot sub-pixel layer.

15. An active matrix OLED apparatus comprising:
a plurality of pixels, each of the plurality of pixels including
a layer of three sub-pixel anodes,
a transparent cathode layer,
a layer of three sub-pixel OLED emitters disposed between the layer of three sub-pixel anodes and the cathode layer, each of the three sub-pixel OLED emitters corresponding to the three sub-pixel anodes, respectively,
a quantum dot semiconductor nanocrystal layer disposed above the transparent cathode layer, the quantum dot layer comprises a first quantum dot sub-pixel layer having a photoluminescent emission in a first wavelength range substantially between 780 to 622 nm, wherein the first quantum dot sub-pixel layer being disposed over one of the three sub-pixel OLED emitters having a light emission wavelength in a second wavelength range substantially between 492 to 455, and
a controller configured to independently address each of the three sub-pixel OLED emitters via the transparent cathode layer and each of the three sub-pixel anodes.

16. The apparatus of claim 15, further comprising a color filter disposed over the first quantum dot sub-pixel layer configured to narrow the wavelength of the photoluminescent emission of the first quantum dot sub-pixel layer.

17. The apparatus of claim 15, wherein the quantum dot semiconductor nanocrystal layer further comprises a second quantum dot sub-pixel layer having a photoluminescent emission in a third wavelength range substantially between 577 to 492 nm.

18. The apparatus of claim 17, wherein the second quantum dot sub-pixel layer being disposed over another one of the three sub-pixel OLED emitters having a light emission wavelength in the second wavelength range.

19. The apparatus of claim 18, further comprising a color filter disposed over the second quantum dot sub-pixel layer configured to narrow the wavelength of the photoluminescent emission of the second quantum dot sub-pixel layer.

20. The apparatus of claim 15, wherein the quantum dot semiconductor nanocrystal layer further comprises a second quantum dot sub-pixel layer being disposed over another one of the three sub-pixel OLED emitters having a light emission wavelength in the third wavelength range.

21. The apparatus of claim 20, further comprising a color filter disposed over the second quantum dot sub-pixel layer configured to narrow the wavelength of the photoluminescent emission of the second quantum dot sub-pixel layer.
